(19) United States
(12) Patent Application Publication
(10) Pub. No.: US 2002/0068428 A1
(43) Pub. Date: Jun. 6, 2002

(54) Semiconductor device and method of manufacturing the same

(76) Inventor: Kazunobu Kuwazawa, Sakata-shi (JP)

Correspondence Address: HOGAN & HARTSON L.L.P., 500 S. GRAND AVENUE, SUITE 1900, LOS ANGELES, CA, 90071-2611, US

(21) Appl. No.: 09/943,094

(22) Filed: Aug. 29, 2001

(30) Foreign Application Priority Data
Sep. 1, 2000 (JP) 2000-265384(P)

(51) Int. Cl. H01L 21/4763

(52) U.S. Cl. 438/618; 438/647; 438/684

(57) ABSTRACT

A semiconductor device comprises a SOI substrate formed of a semiconductor substrate, an insulation layer provided above the semiconductor substrate, and a SOI layer provided above the insulation layer. An impurity layer is provided in the semiconductor substrate. The impurity layer is electrically connected to a wiring layer provided above the SOI layer. The impurity layer can function as either a wiring layer or a resistance layer. This semiconductor device makes it possible to utilize the region above the semiconductor layer efficiently.

Japanese Patent Application No. 2000-265384, filed Sep. 1, 2000, is hereby incorporated by reference in its entirety.

### FIELD OF THE INVENTION

The present invention relates to a semiconductor device and a method of manufacturing the same, and, in particular, to a semiconductor device having an SOI substrate and a method of manufacturing the same.

### BACKGROUND

Recently, as the demand for faster, less power-hungry LSIs has increased, various techniques for forming LSIs on SOI substrates have been proposed.

As shown in FIG. 11, a SOI substrate 410 has a multi-layer structure comprising a semiconductor substrate 420, an insulation layer 430, and a semiconductor layer 440. In general, a semiconductor element (such as a MOSFET) 450 is formed in the semiconductor layer 440.

### SUMMARY

An object of the present invention is to provide a semiconductor device and a method of manufacturing the same that enable efficient utilization of the region above a semiconductor layer.

Semiconductor Device

(A) A first semiconductor device in accordance with a first aspect of the present invention comprises:

a semiconductor substrate having a first conductive layer provided therein;

an insulation layer provided above the semiconductor substrate;

a semiconductor layer provided above the insulation layer; and

a second conductive layer provided above the semiconductor layer or in the semiconductor layer, and electrically connected to the first conductive layer.

In this aspect of the present invention, a first conductive layer is provided in the semiconductor substrate. For that reason, it is possible to not only form the first conductive layer in the semiconductor substrate, but also utilize the region above the semiconductor layer efficiently. As a result, it is possible to increase the degree of integration of the semiconductor device.

The first conductive layer may be formed from an impurity layer. Forming the first conductive layer from an impurity layer makes it possible to form the first conductive layer in the semiconductor substrate by implanting ions of an impurity therein.

The first conductive layer may function as a wiring layer. Alternatively, the first conductive layer may function as a resistance layer.

A connection hole may be provided for connecting the first conductive layer to the second conductive layer, and a contact layer may be provided in the connection hole. In addition, a side wall may be provided in the connection hole.

(B) A second semiconductor device in accordance with a second aspect of the present invention comprises:

a semiconductor substrate having a contact region provided therein;

an insulation layer provided above the semiconductor substrate; and

a semiconductor layer provided above the insulation layer; and

a conductive layer provided above the semiconductor layer or in the semiconductor layer, and has a function of allowing charge to flow into the semiconductor substrate, said contact region being electrically connected to said conductive layer.

The second semiconductor device has a contact region in the semiconductor substrate. The contact region communicates with the conductive layer to allow charge to flow into the semiconductor substrate. As a result, any charge that builds up in the semiconductor layer flows into the semiconductor substrate.

The contact region may be formed from an impurity layer.

A pn junction may be formed by the contact region and the semiconductor substrate. More specifically, there are two possibilities, as follows:

(1) As a first possibility, the semiconductor substrate may be n-type and the contact region may be p-type. In that case, current can flow into the semiconductor substrate.

(2) As a second possibility, the semiconductor substrate may be p-type and the contact region may be n-type. In that case, charged electrons flow into the semiconductor substrate.

A connection hole may be provided for connecting the contact region to the conductive layer, and a contact layer may be provided in the connection hole. In addition, a side wall may be provided in the connection hole.

(C) A third semiconductor device in accordance with a third aspect of the present invention comprises:

a semiconductor substrate having a first electrode provided therein;

an insulation layer provided above the semiconductor substrate;

a semiconductor layer provided above the insulation layer, the semiconductor layer having a second electrode provided therein; and

the first electrode, the second electrode, and the insulation layer in cooperation turning a capacitive element.

In this aspect of the present invention, the first electrode is formed in the semiconductor substrate and the second electrode is formed in the semiconductor layer. An insulation layer between the semiconductor substrate and the semiconductor layer is made to function as a dielectric film for a capacitive element. In other words, a capacitive element can be formed without forming the capacitive element above the semiconductor layer. That enables efficient use of the region above the semiconductor layer. As a result, it is possible to increase the degree of integration of the semiconductor device.

The first electrode may be formed from a first impurity layer. The second electrode may be formed from a second impurity layer.

The first electrode may be connected electrically to a conductive layer provided above the semiconductor layer or in the semiconductor layer. A connection hole may be provided for connecting the first electrode to the conductive layer, and a contact layer may be provided in the connection hole. A side wall may be provided in the connection hole.

Methods of Manufacturing Semiconductor Devices

(A) A first method of manufacturing a semiconductor device in accordance with a fourth aspect of the present invention relates to a semiconductor device including a semiconductor substrate, an insulation layer provided above the semiconductor substrate, and a semiconductor layer provided above the insulation layer, the method comprising:

a step of implanting ions of an impurity into a predetermined region of the semiconductor substrate and forming a first conductive layer from the resulting impurity layer; and

a step of electrically connecting a second conductive layer provided above the semiconductor layer or in the semiconductor layer to the first conductive layer.

The first conductive layer may function as a wiring layer. Alternatively, the first conductive layer may function as a resistance layer.

The method may further comprise:

a step of forming a connection hole for electrically connecting the first conductive layer to the second conductive layer; and

a step of forming a contact layer in the connection hole.

It may further comprise a step of forming a side wall in the connection hole.

(B) A second method of manufacturing a semiconductor device in accordance with a fifth aspect of the present invention relates to a semiconductor device including a semiconductor substrate, an insulation layer provided above the semiconductor substrate, and a semiconductor layer provided above the insulation layer, wherein a contact region is provided in the semiconductor substrate, and the contact region is connected electrically to a conductive layer provided above the semiconductor layer or in the semiconductor layer, and has a function of allowing charge to flow into the semiconductor substrate, the method comprising:

a step of forming the contact region by implantation of ions of an impurity into the semiconductor substrate; and

a step of electrically connecting the contact region to the conductive layer.

The method may further comprise:

a step of forming a contact hole for electrically connecting the contact region to the conductive layer formed in the semiconductor layer; and

a step of forming a contact layer in the connection hole.

The method may further comprise a step of forming a side wall in the connection hole.

(C) A third method of manufacturing a semiconductor device in accordance with a sixth aspect of the present invention relates to a semiconductor device including a semiconductor substrate, an insulation layer provided above the semiconductor substrate, and a semiconductor layer provided above the insulation layer, the method comprising:

a step of forming a capacitive element, wherein the capacitive element is formed from a first electrode provided in the semiconductor substrate, the insulation layer, and a second electrode provided in the semiconductor layer,

wherein the step of forming the capacitive element comprises a step of implanting ions of an impurity into the semiconductor substrate to form the first electrode from a first impurity layer.

The step of forming the capacitive element may further comprise a step of implanting ions of an impurity into the semiconductor layer and forming the second electrode from the second impurity layer.

This semiconductor device may have a conductive layer provided above the semiconductor layer or in the semiconductor layer, and

the method further comprises:

a step of forming a connection hole for electrically connecting the first electrode to the conductive layer; and

a step of forming a contact layer in the connection hole.

The method may further comprise a step of forming a side wall in the connection hole.

### BRIEF DESCRIPTION OF THE DRAWINGS

FIG. 1 is a schematic sectional view through a semiconductor device in accordance with a first embodiment of the present invention;

FIGS. 2A and 2B are schematic sectional views showing steps in a process of manufacturing the semiconductor device in accordance with the first embodiment;

FIGS. 3A and 3B are schematic sectional views showing further steps in the process of manufacturing the semiconductor device in accordance with the first embodiment;

FIG. 4 is a schematic plan view of an example of the application of an impurity layer that functions as a wiring layer;

FIG. 5 is a schematic sectional view through a semiconductor device in accordance with a second embodiment of the present invention;

FIGS. 6A and 6B are schematic sectional views showing steps in a process of manufacturing the semiconductor device in accordance with the second embodiment;

FIGS. 7A, 7B, and 7C are schematic sectional views showing further steps in the process of manufacturing the semiconductor device in accordance with the second embodiment;

FIG. 8 is a schematic sectional view through a semiconductor device in accordance with a third embodiment of the present invention;

FIG. 9 is a schematic sectional view showing a step in a process of manufacturing the semiconductor device in accordance with the third embodiment;

FIGS. 10A and 10B are schematic sectional views showing further steps in the process of manufacturing the semiconductor device in accordance with the third embodiment;

FIG. 11 is a schematic sectional view through a semiconductor device having a SOI substrate in accordance with the conventional art; and

FIG. 12 is a schematic sectional view through a modified example of the first embodiment.

### DETAILED DESCRIPTION OF THE PREFERRED EMBODIMENTS

Preferred embodiments of the present invention are described below with reference to the accompanying figures.

First Embodiment

Semiconductor Device

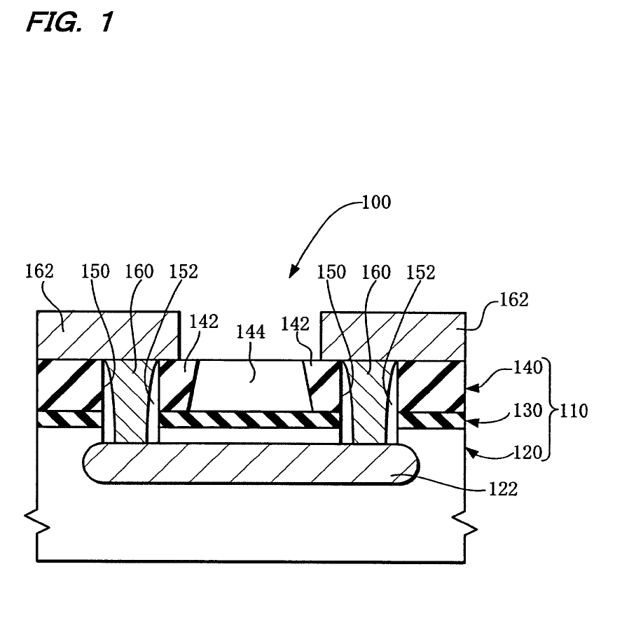

The description below concerns a semiconductor device in accordance with the first embodiment of the present invention. A schematic sectional view through the semiconductor device of this first embodiment is shown in FIG. 1.

A semiconductor device 100 has an SOI substrate 110. The SOI substrate 110 has a multi-layer structure comprising a semiconductor substrate 120, an insulation layer 130, and a SOI layer (semiconductor layer) 140. A trench element isolation region 142 is formed in a predetermined region of the SOI layer 140.

An impurity layer 122 is formed in the semiconductor substrate 120. This impurity layer 122 functions as a wiring layer. The impurity concentration of the impurity layer 122 is determined from consideration of the desired conductivity of the wiring layer.

A connection hole 150 is formed in a predetermined region of the SOI substrate 110 to extend as far as the impurity layer 122. A side wall 152 is formed on a side surface of the SOI substrate 110 in the connection hole 150. A contact layer 160 is formed in the connection hole 150. If the connection hole 150 is formed in an active element region 144, the side wall 152 acts to prevent short-circuiting between the active element region 144 and the contact layer 160. A wiring layer 162 is formed above the SOI layer 140 and the contact layer 160.

The description now turns to the operational effects of the semiconductor device in accordance with this first embodiment.

(a) In this embodiment of the invention, the impurity layer 122 that functions as a wiring layer is formed in the semiconductor substrate 120. For that reason, not only is the impurity layer 122 formed in the semiconductor substrate 120, but it is also possible to utilize the region above the SOI layer 140 efficiently. As a result, this embodiment of the invention makes it possible to increase the degree of integration of the semiconductor device.

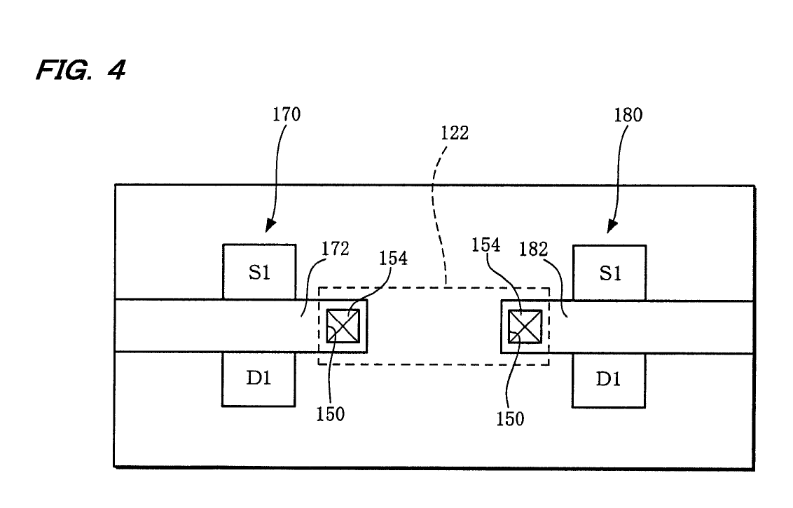

(b) The impurity layer 122, which is formed in the semiconductor substrate 120 and functions as a wiring layer, can be applied to connect a gate electrode 172 in a first transistor region 170 and a gate electrode 182 in a second transistor region 180, as shown by way of example in FIG. 4. Note that S1 denotes a source region and D1 denotes a drain region.

Method of Manufacturing Semiconductor Device

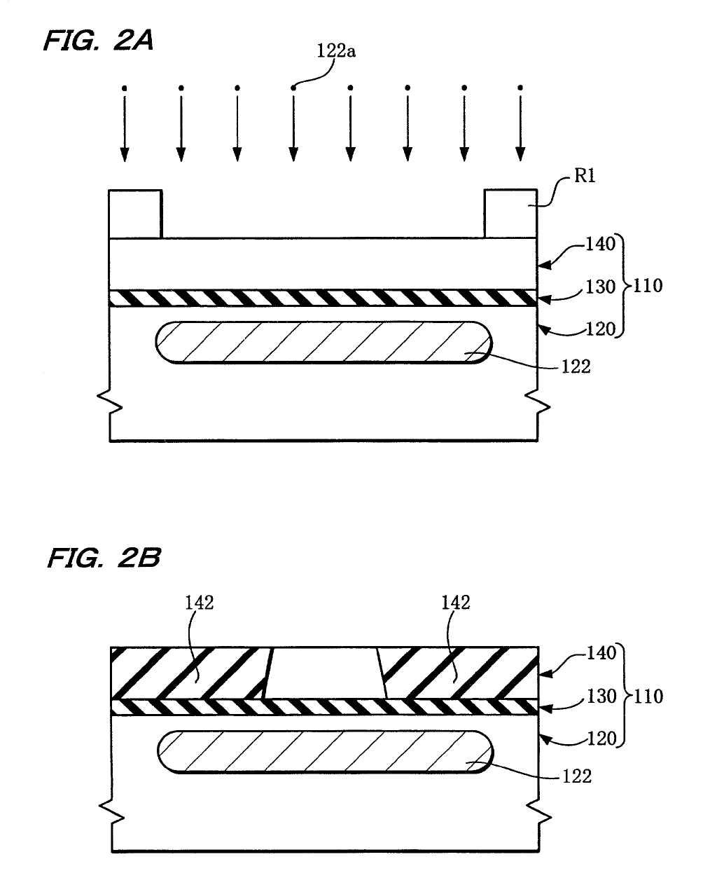

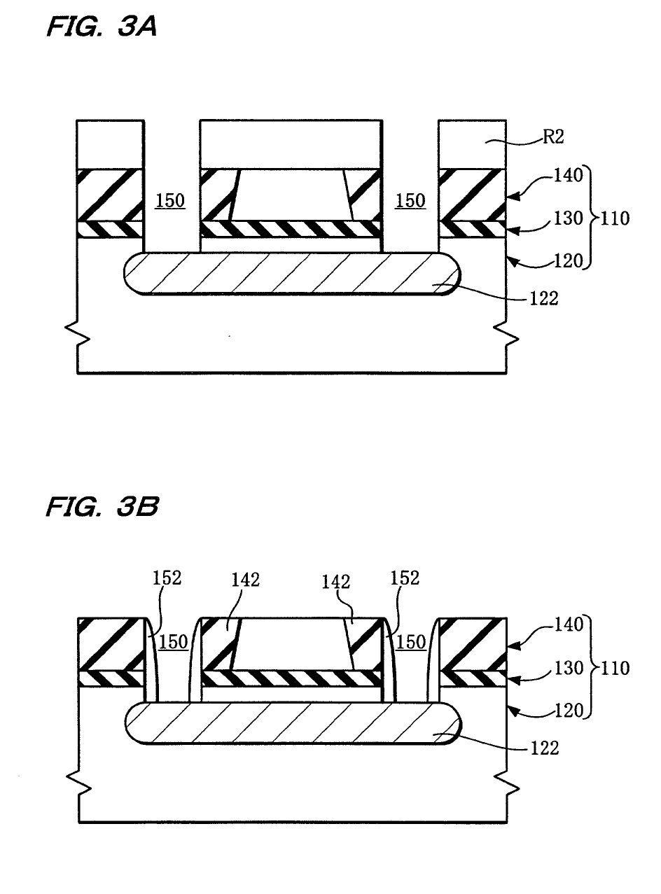

A method of manufacturing the semiconductor device in accordance with the first embodiment of the present invention is described below. Schematic sectional views showing steps in the manufacture of the semiconductor device of this embodiment are shown in FIGS. 2A, 2B, 3A, 3B, and 3C.

(a) First of all, a first resist layer R1 is formed above the SOI layer 140, as shown in FIG. 2A. The first resist layer R1 has an aperture above the region that is intended for the formation of the impurity layer 122.

The first resist layer R1 is then used as a mask to implant ions of an impurity 122a into the semiconductor substrate 120. This forms the impurity layer 122 in the semiconductor substrate 120. The first resist layer R1 is then removed by ashing.

(b) Next, the trench element isolation region 142 is formed by a known method in a predetermined region of the SOI layer 140, as shown in FIG. 2B.

(c) A second resist layer R2 is then formed above the SOI layer 140, as shown in FIG. 3A. The second resist layer R2 has an aperture above the region that is intended for the formation of the connection hole 150. The second resist layer R2 is then used as a mask to etch the SOI layer 140, the insulation layer 130, and the semiconductor substrate 120, to form the connection hole 150. Reactive ion etching could be used as the etching method. The second resist layer R2 is then removed.

(d) The side wall 152 is then formed on the side surfaces of the SOI substrate 110 in the connection hole 150, as shown in FIG. 3B. The side wall 152 could be formed by a method such as the one described below. An insulation layer (not shown in the figure) is formed on the SOI layer 140 in such a manner as to fill the connection hole 150. The insulation layer could be formed by a method such as CVD, by way of example. The side wall 152 could be formed by using reactive ion etching of the insulation layer.

(e) The contact layer 160 is then formed in the connection hole 150, as shown in FIG. 1. The contact layer 160 could be formed by first forming a conductive layer on the SOI layer 140 so as to fill the connection hole 150, followed by etching that conductive layer away. The material of the contact layer 160 could be polysilicon, tungsten, aluminum, or titanium. If necessary, a wetting layer or a barrier layer could be formed in the connection hole 150 before the formation of the conductive layer.

The wiring layer 162 having a predetermined pattern is then formed above the SOI layer 140. This completes the semiconductor device 100 in accordance with this first embodiment of the present invention.

Modifications

The first embodiment of the invention can be modified as described below, by way of example.

(1) In the above-described embodiment, the impurity layer 122 functions as a wiring layer. However, the impurity layer 122 could also function as a resistance layer. In such a case, the impurity concentration of the impurity layer 122 is determined from consideration of the desired resistance.

(2) In the above-described embodiment, the impurity layer 122 is connected to the wiring layer 162 formed above the SOI layer 140. However, the impurity layer 122 is not limited thereto and thus it could also be connected to a conductive layer formed in the SOI layer 140.

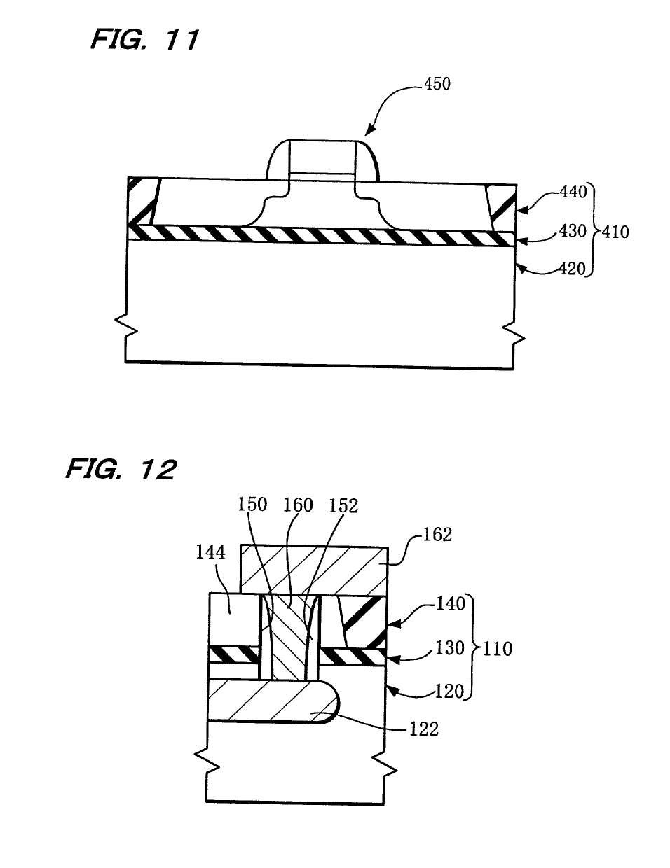

(3) In the above-described embodiment, the connection hole 150 is formed in the trench element isolation region 142. However, the connection hole 150 is not limited thereto and thus it could also be formed in the active element region 144, as shown in FIG. 12. These modifications can also be applied in a similar manner to the embodiments described below.

Second Embodiment

Semiconductor Device

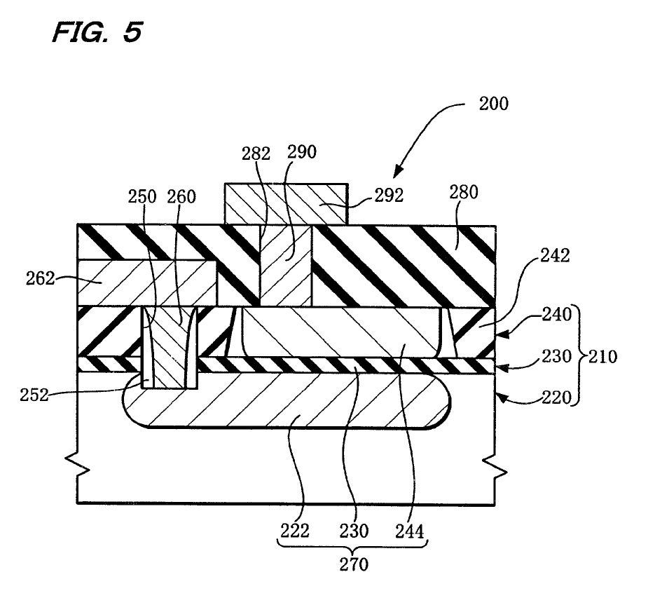

The description now turns to a semiconductor device in accordance with a second embodiment of the present invention. A schematic sectional view through the semiconductor device of this second embodiment is shown in FIG. 5.

A semiconductor device 200 has a SOI substrate 210. The SOI substrate 210 has a multi-layer structure comprising a semiconductor substrate 220, an insulation layer 230, and a SOI layer (semiconductor layer) 240. A trench element isolation region 242 is formed in a predetermined region of the SOI layer 240.

A first impurity layer 222 is formed in the semiconductor substrate 220. A second impurity layer 244 is formed in the trench element isolation region 242 in the SOI layer 240. A capacitive element 270 is formed of the first impurity layer 222, the insulation layer 230, and the second impurity layer 244. In other words, the first impurity layer 222 functions as a lower electrode thereof, the insulation layer 230 functions as a dielectric film, and the second impurity layer 244 functions as an upper electrode.

The impurity concentration of the first impurity layer 222 is determined from consideration of the desired characteristics of the capacitive element 270. The impurity concentration of the second impurity layer 244 is determined from consideration of the desired characteristics of the capacitive element 270. The thickness of the insulation layer 230 is determined from consideration of the desired characteristics of the capacitive element 270.

A connection hole 250 is formed in a predetermined region of the SOI substrate 210 to extend as far as the first impurity layer 222. A side wall 252 is formed on a side surface of the SOI substrate 210 in the connection hole 250. A first contact layer 260 is formed in the connection hole 250. If the connection hole 250 is formed in an active element region, the side wall 252 acts to prevent short-circuiting between the active element region and the first contact layer 260. A first wiring layer 262 having a predetermined pattern is formed above the SOI layer 240 and the first contact layer 260.

An interlayer dielectric 280 is formed above the SOI layer 240 and the first wiring layer 262. A through-hole 282 is formed in a predetermined region of the interlayer dielectric 280. The through-hole 282 extends as far as the second impurity layer 244. A second contact layer 290 is formed in the through-hole 282. A second wiring layer 292 having a predetermined pattern is formed above the interlayer dielectric 280 and the second contact layer 290.

The description now turns to the operational effect of the semiconductor device in accordance with this second embodiment.

In this embodiment of the present invention, the capacitive element 270 is formed from the first impurity layer 222 formed in the semiconductor substrate 220, the insulation layer 230, and the second impurity layer 244 formed in the SOI layer 240. For that reason, it suffices to form the capacitive element above the SOI layer 240. As a result, the region above the SOI layer 240 can be utilized efficiently. It therefore makes it possible to increase the degree of integration of the semiconductor device.

Method of Manufacturing Semiconductor Device

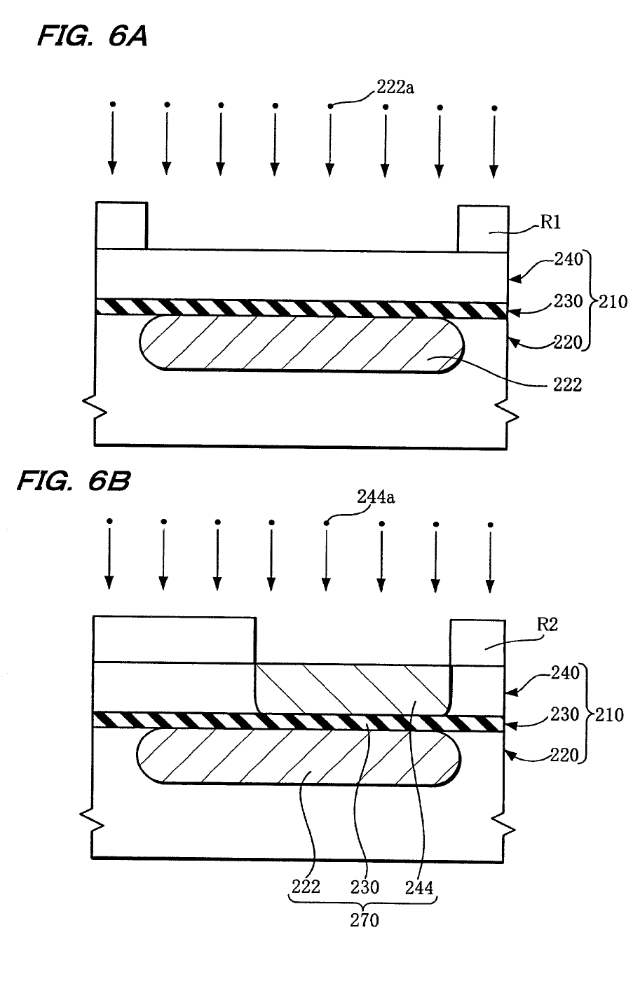

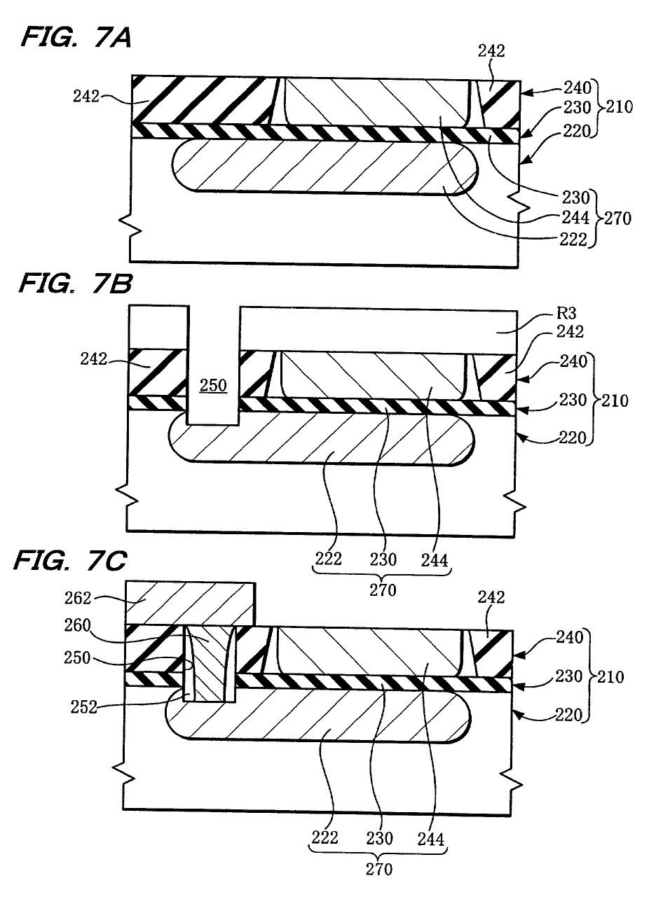

A method of manufacturing the semiconductor device in accordance with the second embodiment of the present invention is described below. Schematic sectional views showing steps in the manufacture of the semiconductor device of this embodiment are shown in FIGS. 6A, 6B, 7A, 7B, and FIG. 7C.

(a) First of all, a first resist layer R1 is formed above the SOI layer 240. The first resist layer R1 has an aperture above the region that is intended for the formation of the first impurity layer 222.

The first resist layer R1 is then used as a mask for the implantation of ions of an impurity 222a into the semiconductor substrate 220. This forms the first impurity layer 222 in the semiconductor substrate 220. The first resist layer R1 is then removed.

(b) A second resist layer R2 is then formed above the SOI layer 240. The second resist layer R2 has an aperture in a region that is intended for the formation of the second impurity layer 244.

The second resist layer R2 is used as a mask for the implantation of ions of an impurity 244a into the SOI layer 240. This forms the second impurity layer 244 in the SOI layer 240. The formation of the second impurity layer 244 completes the formation of the capacitive element 270 comprising the first impurity layer 222, the insulation layer 230, and the second impurity layer 244. The second resist layer R2 is removed.

(c) Next, the trench element isolation region 242 is formed by a known method in a predetermined region of the SOI layer 240, as shown in FIG. 7A.

(d) A third resist layer R3 is then formed above the SOI layer 240, as shown in FIG. 7B. The third resist layer R3 has an aperture above a region that is intended for the formation of the connection hole 250.

The third resist layer R3 is used as a mask for etching the SOI layer 240, the insulation layer 230, and the semiconductor substrate 220, to form the connection hole 250. This could be done by reactive ion etching, by way of example. The third resist layer R3 is then removed.

(e) The side wall 252 is then formed on the side surface of the SOI substrate 210 in the connection hole 250, as shown in FIG. 7C. The side wall 252 could be formed in a manner similar to that of the first embodiment.

The first contact layer 260 is formed in the connection hole 250. The first contact layer 260 could be formed in a manner similar to that of the first embodiment. If necessary, a wetting layer or a barrier layer could be formed in the connection hole 250 before the formation of the conductive layer.

The first wiring layer 262 having a predetermined pattern is then formed above the SOI layer 240.

(f) The interlayer dielectric 280, which is formed of a silicon oxide layer, is then formed by a method such as CVD above the SOI layer 240 and the first wiring layer 262. A predetermined region of the interlayer dielectric 280 is selectively etched away to form the through-hole 282 as far as the second impurity layer 244. After than, the second contact layer 290 is formed in the through-hole 282. The second wiring layer 292 having a predetermined pattern is formed above the interlayer dielectric 280 the second contact layer 290. This completes the semiconductor device 200 in accordance with the second embodiment of the invention.

Modifications

The second embodiment of the invention can be modified as described below, by way of example.

In the above-described embodiment, the first impurity layer 222 is connected to the first wiring layer 262 formed above the SOI layer 240. However, the first impurity layer 222 is not limited thereto and thus it could be connected to a conductive layer formed in the SOI layer 240.

Third Embodiment

Semiconductor Device

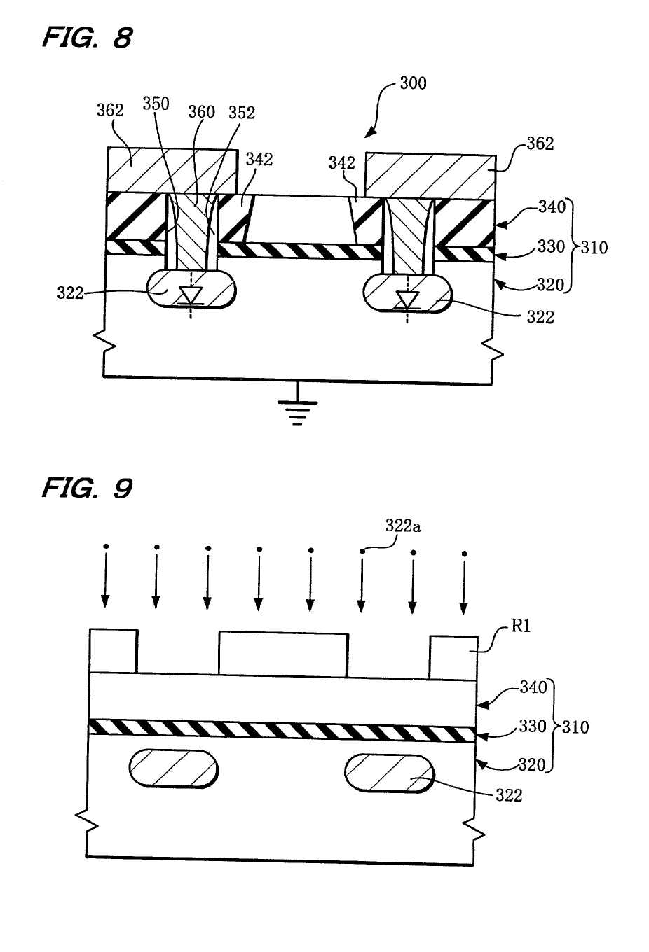

The description now turns to a semiconductor device in accordance with a third embodiment of the present invention. A schematic sectional view through the semiconductor device of this second embodiment is shown in FIG. 8.

A semiconductor device 300 has a SOI substrate 310. The SOI substrate 310 has a multi-layer structure comprising a semiconductor substrate 320, an insulation layer 330, and a SOI layer (semiconductor layer) 340. A trench element isolation region 342 is formed in a predetermined region of the SOI layer 340.

The conductivity of the semiconductor substrate 320 is n-type. An impurity layer (contact region) 322 is formed in the semiconductor substrate 320. The impurity layer 322 has the function of making charge flow into the semiconductor substrate 320. The impurity layer 322 is p-type. In other words, a pn-junction diode is formed by the impurity layer 322 and the semiconductor substrate 320.

A connection hole 350 is formed in a predetermined region of the SOI substrate 310 to extend as far as the impurity layer 322. A side wall 352 is formed on a side surface of the SOI substrate 310 in the connection hole 350. A contact layer 360 is formed in the connection hole 350. If the connection hole 350 is formed in an active element region, the side wall 352 acts to prevent short-circuiting between the active element region and the contact layer 360. A wiring layer 362 having a predetermined pattern is formed above the SOI layer 340 and the contact layer 360.

The description now turns to the operational effects of the semiconductor device in accordance with this third embodiment.

In this embodiment of the invention, the impurity layer 322 is formed in the semiconductor substrate 320 to communicate with the wiring layer 362. A pn-junction diode is formed from this impurity layer 322 and the semiconductor substrate 320. For that reason, current is released into the semiconductor substrate 320 through the pn-junction diode. The impurity layer 322 can therefore function as an electrostatic protection region.

Method of Manufacturing Semiconductor Device

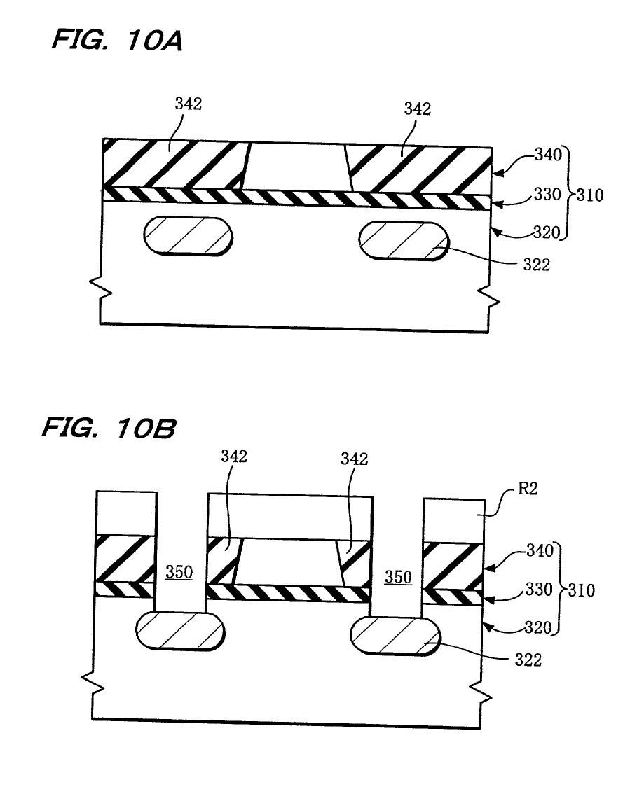

A method of manufacturing the semiconductor device in accordance with the third embodiment of the present invention is described below. Schematic sectional views showing steps in the manufacture of the semiconductor device of this embodiment are shown in FIGS. 9, 10A, and 10B.

(a) First of all, the SOI substrate 310 having an n-type semiconductor substrate is prepared. A first resist layer R1 is then formed above the SOI layer 340, as shown in FIG. 9. The first resist layer R1 has an aperture above a region that is intended for the formation of the impurity layer 322.

The first resist layer R1 is then used as a mask for the implantation of ions of a p-type impurity 322a into the semiconductor substrate 320. This forms the p-type impurity layer 322 in the semiconductor substrate 320. The formation of the p-type impurity layer 322 forms a pn-junction diode at the boundary of the impurity layer 322. The first resist layer R1 is then removed.

(b) The trench element isolation region 342 is then formed by a known method in a predetermined region of the SOI layer 340, as shown in FIG. 10A.

(c) A second resist layer R2 is formed above the SOI layer 340, as shown in FIG. 10B. The second resist layer R2 has an aperture above a region that is intended for the formation for the connection hole 350, extending as far as the impurity layer 322.

The second resist layer R2 is used as a mask for etching the SOI layer 340, the insulation layer 330, and the semiconductor substrate 320, to form the connection hole 350. This could be done by reactive ion etching, by way of example. The second resist layer R2 is then removed.

(d) Next, the sidewall 352 is formed on a side surface of the SOI substrate 310 in the connection hole 350, as shown in FIG. 8. The side wall 352 could be formed in a manner similar to that of the first embodiment.

The contact layer 360 is then formed in the connection hole 350. The contact layer 360 could be formed in a manner similar to that of the first embodiment. If necessary, a wetting layer or a barrier layer could be formed in the connection hole 350 before the formation of the conductive layer. The wiring layer 362 having a predetermined pattern is then formed above the SOI layer 340. This completes the formation of the semiconductor device in accordance with this third embodiment of the present invention.

The description now turns to the function and effects of a semiconductor device in accordance with this embodiment of the invention.

(a) This embodiment comprises a step of forming the impurity layer 322 that, together with the semiconductor substrate 320, forms a pn-junction diode in the semiconductor substrate 320. For that reason, any charge generated by the steps of implanting ions of an impurity or the etching step can be released to the semiconductor substrate 320 through the pn-junction diode during the manufacture process. As a result, it is possible to prevent destruction of the semiconductor element by this charge.

Modifications

The third embodiment of the invention can be modified as described below, by way of example.

(1) In the third embodiment, the impurity layer 322 is p-type and the semiconductor substrate 320 is n-type. However, it should be obvious that these elements are not limited thereto, and thus the impurity layer 322 can be n-type and the insulation layer 320 can be p-type. In that case, electron charges can be released to the semiconductor substrate 320 through the impurity layer 322.

(2) In the above-described embodiment, the impurity layer 322 is connected to the wiring layer 362 formed above the SOI layer 340. However, the impurity layer 322 is not limited thereto and thus it can be connected to a conductive layer formed in the SOI layer 340.

It should be noted that the present invention is not limited to the above described embodiments and thus it can be modified in various ways without departing from the scope of the invention described herein.

What is claimed is:

1. A semiconductor device comprising:
a semiconductor substrate having a first conductive layer provided therein;
an insulation layer provided above the semiconductor substrate;
a semiconductor layer provided above the insulation layer; and
a second conductive layer provided above the semiconductor layer or in the semiconductor layer, and electrically connected to the first conductive layer.

2. The semiconductor device as defined by claim 1,
wherein the first conductive layer is formed from an impurity layer.

3. The semiconductor device as defined by claim 1,
wherein the first conductive layer functions as a wiring layer.

4. The semiconductor device as defined by claim 1,
wherein the first conductive layer functions as a resistance layer.

5. The semiconductor device as defined by claim 1,
wherein a connection hole is provided for connecting the first conductive layer to the second conductive layer, and
wherein a contact layer is provided in the connection hole.

6. The semiconductor device as defined by claim 1,
wherein a side wall is provided in the connection hole.

7. A semiconductor device comprising:
a semiconductor substrate having a contact region provided therein;
an insulation layer provided above the semiconductor substrate; and
a semiconductor layer provided above the insulation layer; and
a conductive layer provided above the semiconductor layer or in the semiconductor layer, and has a function of allowing charge to flow into the semiconductor substrate, said contact region being electrically connected to said conductive layer.

8. The semiconductor device as defined by claim 7,
wherein the contact region is formed from an impurity layer.

9. The semiconductor device as defined by claim 7,
wherein a pn junction is formed by the contact region and the semiconductor substrate.

10. The semiconductor device as defined by claim 9,
wherein the semiconductor substrate is n-type, and
wherein the contact region is p-type.

11. The semiconductor device as defined by claim 9,
wherein the semiconductor substrate is p-type, and
wherein the contact region is n-type.

12. The semiconductor device as defined by claim 7,
wherein a connection hole is provided for connecting the contact region to the conductive layer, and
wherein a contact layer is provided in the connection hole.

13. The semiconductor device as defined by claim 12,
wherein a side wall is provided in the connection hole.

14. A semiconductor device comprising:
a semiconductor substrate having a first electrode provided therein;
an insulation layer provided above the semiconductor substrate;
a semiconductor layer provided above the insulation layer, the semiconductor layer having a second electrode provided therein; and
the first electrode, the second electrode, and the insulation layer in cooperation turning a capacitive element.

15. The semiconductor device as defined by claim 14,
wherein the first electrode is formed from a first impurity layer.

16. The semiconductor device as defined by claim 14,
wherein the second electrode is formed from a second impurity layer.

17. The semiconductor device as defined by claim 14,
wherein the first electrode is connected electrically to a conductive layer provided above the semiconductor layer or in the semiconductor layer.

18. The semiconductor device as defined by claim 17,
wherein a connection hole is provided for connecting the first electrode to the conductive layer, and
wherein a contact layer is provided in the connection hole.

19. The semiconductor device as defined by claim 18,
wherein a side wall is provided in the connection hole.

20. A method of manufacturing a semiconductor device, the semiconductor device including a semiconductor substrate, an insulation layer provided above the semiconductor substrate, and a semiconductor layer provided above the insulation layer, the method comprising:
a step of implanting ions of an impurity into a predetermined region of the semiconductor substrate and forming a first conductive layer from the resulting impurity layer; and
a step of electrically connecting a second conductive layer provided above the semiconductor layer or in the semiconductor layer to the first conductive layer.

21. The method of manufacturing a semiconductor device as defined by claim 20,
wherein the first conductive layer functions as a wiring layer.

22. The method of manufacturing a semiconductor device as defined by claim 20,
wherein the first conductive layer functions as a resistance layer.

23. The method of manufacturing a semiconductor device as defined by claim 20, further comprising:
a step of forming a connection hole for electrically connecting the first conductive layer to the second conductive layer; and
a step of forming a contact layer in the connection hole.

24. The method of manufacturing a semiconductor device as defined by claim 23, further comprising:
a step of forming a side wall in the connection hole.

25. A method of manufacturing a semiconductor device including a semiconductor substrate, an insulation layer provided above the semiconductor substrate, and a semiconductor layer provided above the insulation layer, wherein a contact region is provided in the semiconductor substrate, and the contact region is connected electrically to a conductive layer provided above the semiconductor layer or in the semiconductor layer, and has a function of allowing charge to flow into the semiconductor substrate, the method comprising:
a step of forming the contact region by implantation of ions of an impurity into the semiconductor substrate; and
a step of electrically connecting the contact region to the conductive layer.

26. The method of manufacturing a semiconductor device as defined by claim 25, further comprising:
a step of forming a contact hole for electrically connecting the contact region to the conductive layer formed in the semiconductor layer; and
a step of forming a contact layer in the connection hole.

27. The method of manufacturing a semiconductor device as defined by claim 26, further comprising:
a step of forming a side wall in the connection hole.

28. A method of manufacturing a semiconductor device including a semiconductor substrate, an insulation layer provided above the semiconductor substrate, and a semiconductor layer provided above the insulation layer, the method comprising:
a step of forming a capacitive element, wherein the capacitive element is formed from a first electrode provided in the semiconductor substrate, the insulation layer, and a second electrode provided in the semiconductor layer,
wherein the step of forming the capacitive element comprises a step of implanting ions of an impurity into the semiconductor substrate to form the first electrode from a first impurity layer.

29. The method of manufacturing a semiconductor device as defined by claim 28,
wherein the step of forming the capacitive element further comprises a step of implanting ions of an impurity into the semiconductor layer to form the second electrode from a second impurity layer.

30. The method of manufacturing a semiconductor device as defined by claim 28,
wherein the semiconductor device has a conductive layer provided above the semiconductor layer or in the semiconductor layer, and
wherein the method further comprises:
a step of forming a connection hole for electrically connecting the first electrode to the conductive layer; and
a step of forming a contact layer in the connection hole.

31. The method of manufacturing a semiconductor device as defined by claim 30, further comprising a step of forming a side wall in the connection hole.
